(19) United States
(12) Patent Application Publication
(10) Pub. No.: US 2026/0333871 A1
(43) Pub. Date: Oct. 22, 2026

(54) WIRING BOARD, DISPLAY DEVICE, AND METHOD OF MANUFACTURING WIRING BOARD

(71) Applicant: Sharp Display Technology Corporation, Kameyama City (JP)

(72) Inventors: Junichi SATOH, Kameyama City (JP); Shohei AKUTSU, Kameyama City (JP); Akifumi MORISHIMA, Kameyama City (JP); Ryuji MATSUMOTO, Kameyama City (JP)

(21) Appl. No.: 19/642,925

(22) Filed: Apr. 9, 2026

(30) Foreign Application Priority Data
Apr. 17, 2025 (JP) 2025-067911

(51) Int. Cl. H10D 86/40; H10D 86/01

(52) U.S. Cl. CPC H10D 86/441; H10D 86/021

(57) ABSTRACT

A wiring board includes a first wiring line including a part of a first conductive layer and extending in a first direction, a repairing wiring line including a part of the first conductive layer, disposed at a location that is separated by a distance from the first wiring line, and extending in the first direction, and a first connecting segment including a part of a conductive member, extending across the first wiring line and the repairing wiring line, and connected to each of the first wiring line and the repairing wiring line, the conductive member being provided on an upper layer side of the first conductive layer. The repairing wiring line is shorter in the first direction than the first wiring line and comprises a plurality of repairing wiring lines arranged at intervals in the first direction.

### CROSS-REFERENCE TO RELATED APPLICATIONS

The present application claims priority from Japanese Application JP2025-067911, the content of which is hereby incorporated by reference into this application.

### BACKGROUND

### Technical Field

The present specification discloses techniques related to a wiring board, a display device, and a method of manufacturing a wiring board all of which improve the reliability of repairs.

The wiring board described in JP2000-250436A has been known as an example of a wiring board used in a display device. JP2000-250436A describes a thin film transistor array as a wiring board. The thin film transistor array described in JP2000-250436A includes, on a transparent insulation substrate made of, for example, glass: a plurality of scan lines fabricated from a first conductive film; a plurality of signal lines fabricated from a second conductive film; pixel electrodes each provided on a gate insulation film in a region surrounded by adjacent scan lines and adjacent signal lines; thin film transistors each connected to one of the pixel electrodes; and a light-blocking film fabricated from the first conductive film to form light-blocking overlapping segments via the gate insulation film and a periphery facing the signal line of each pixel electrode, wherein the neighborhoods of both ends of the light-blocking film along the signal line project toward the signal line to form correction-use overlapping segments that overlap each other via the signal line and the gate insulation film.

In the manufacture of the thin film transistor array described in JP2000-250436A, if the signal line breaks, the signal line is repaired by irradiating, with laser, the two correction-use overlapping segments that sandwich the break in the signal line to restore electrical conductance between the light-blocking film and the signal line at the site irradiated with the laser. However, there are cases where the light-blocking film and the signal line may not be properly connected by laser irradiation, depending on conditions including the shape of the site in the broken signal line irradiated with a laser beam. In other words, there has been a problem that the normalization of a signal line through repair using a laser beam has low reliability.

The techniques described in the present specification have been completed in view of these circumstances and have an object to improve the reliability of repairs.
1. A wiring board in accordance with a technique described in the present specification includes: a first wiring line including a part of a first conductive layer and extending in a first direction; a repairing wiring line including a part of the first conductive layer, disposed at a location that is separated by a distance from the first wiring line, and extending in the first direction; and a first connecting segment including a part of a conductive member, extending across the first wiring line and the repairing wiring line, and connected to each of the first wiring line and the repairing wiring line, the conductive member being provided on an upper layer side of the first conductive layer, wherein the repairing wiring line is shorter in the first direction than the first wiring line and includes a plurality of repairing wiring lines arranged at intervals in the first direction.
2. Additionally, the wiring board may be configured, in addition to (1) described above, so that each of the first wiring line and the plurality of repairing wiring lines has an end portion in terms of a second direction that crosses the first direction, the end portions having a forward-tapered cross-sectional shape.
3. Additionally, the wiring board may be configured, in addition to (1) or (2) described above, so as to further include a second connecting segment including a part of the conductive member, extending across two of the plurality of repairing wiring lines that are adjacent to each other in the first direction, and connected to each of the two of the plurality of repairing wiring lines.
4. Additionally, the wiring board may be configured, in addition to (3) described above, so that each of the plurality of repairing wiring lines has an end portion in terms of the first direction, the end portions having a forward-tapered cross-sectional shape.
5. Additionally, the wiring board may be configured, in addition to any one of (1) to (4) described above, so that the first connecting segment includes two first connecting segments that are separated by a distance in the first direction, and the first wiring line has a broken portion at a location sandwiched between the two first connecting segments that are separated by a distance in the first direction.
6. A display device in accordance with a technique described in the present specification includes: the wiring board of any one of (1) to (5) described above; and an opposite substrate disposed opposite the wiring board.
7. A method of manufacturing a wiring board in accordance with a technique described in the present specification includes: providing a first wiring line including a part of a first conductive layer and extending in a first direction; providing a plurality of repairing wiring lines arranged at intervals in the first direction, each of the plurality of repairing wiring lines including a part of the first conductive layer, disposed at a location that is separated by a distance from the first wiring line, extending in the first direction, and being shorter in the first direction than the first wiring line; and providing a first connecting segment including a part of a conductive member, extending across the first wiring line and the plurality of repairing wiring lines, and connected to each of the first wiring line and the plurality of repairing wiring lines, the conductive member being provided on an upper layer side of the first conductive layer.

### Advantageous Effects of the Disclosure

The techniques described in the present specification can improve the reliability of repairs.

### BRIEF DESCRIPTION OF DRAWINGS

FIG. 1 is a plan view of a liquid crystal panel, a driver, and a flexible substrate in a liquid crystal display device in accordance with Embodiment 1.

FIG. 2 is a cross-sectional view of a liquid crystal panel, a driver, and a flexible substrate in accordance with Embodiment 1.

FIG. 3 is a circuit diagram of an electrical configuration of an array substrate in the liquid crystal panel in accordance with Embodiment 1.

FIG. 4 is a plan view of a pixel arrangement on the array substrate in accordance with Embodiment 1.

FIG. 5 is a cross-sectional view of the liquid crystal panel in accordance with Embodiment 1 taken along line v-v shown in FIG. 4.

FIG. 6 is a cross-sectional view of the array substrate in accordance with Embodiment 1 taken along line vi-vi shown in FIG. 4.

FIG. 7 is a cross-sectional view of the array substrate in accordance with Embodiment 1 taken along line vii-vii shown in FIG. 4.

FIG. 8 is a cross-sectional view of the array substrate in accordance with Embodiment 1 taken along line viii-viii shown in FIG. 4.

FIG. 9 is a cross-sectional view of the array substrate in accordance with Embodiment 1 taken along line ix-ix shown in FIG. 4.

FIG. 10 is a plan view showing source electrodes, drain electrodes, and source lines having been formed as a result of a fourth step of an array substrate manufacturing step in accordance with Embodiment 1.

FIG. 11 is a cross-sectional view of the array substrate in accordance with Embodiment 1 taken along line xi-xi shown in FIG. 10.

FIG. 12 is a plan view showing a first connecting segment having been formed as a result of an inspection step and a repair step in the array substrate manufacturing step in accordance with Embodiment 1.

FIG. 13 is a cross-sectional view of the array substrate in accordance with Embodiment 1 taken along line xiii-xiii shown in FIG. 12.

FIG. 14 is a plan view showing source electrodes, drain electrodes, and source lines having been formed as a result of the fourth step in the array substrate manufacturing step in accordance with Embodiment 1.

FIG. 15 a plan view showing a first connecting segment and a second connecting segment having been formed as a result of the inspection step and the repair step in the array substrate manufacturing step in accordance with Embodiment 1.

FIG. 16 is a cross-sectional view of the array substrate in accordance with Embodiment 1 taken along line xvi-xvi shown in FIG. 15.

### DESCRIPTION OF EMBODIMENTS

### Embodiment 1

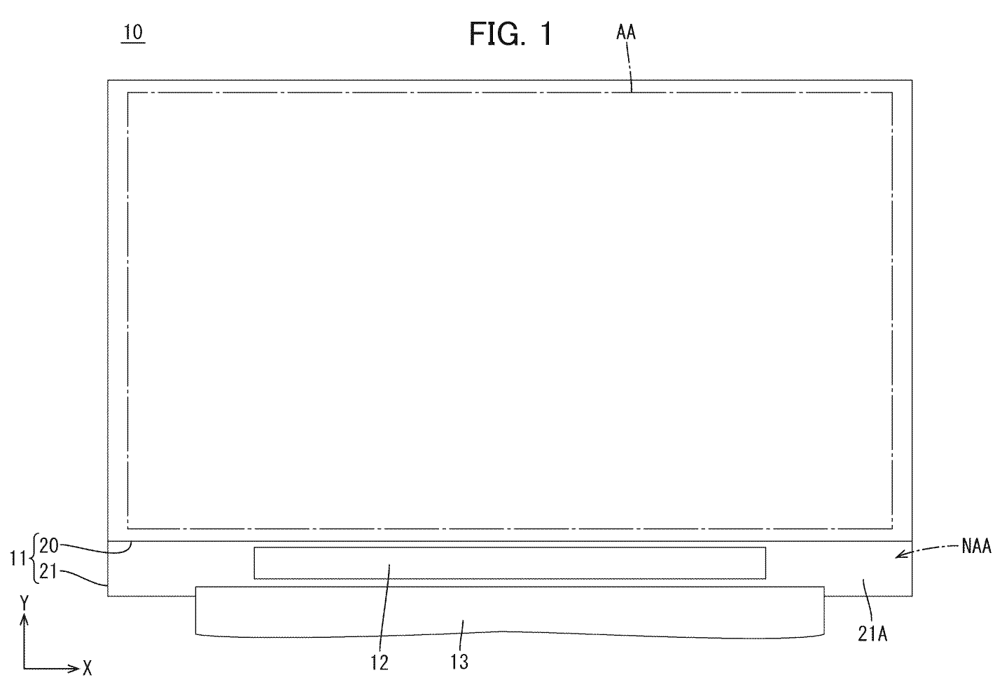

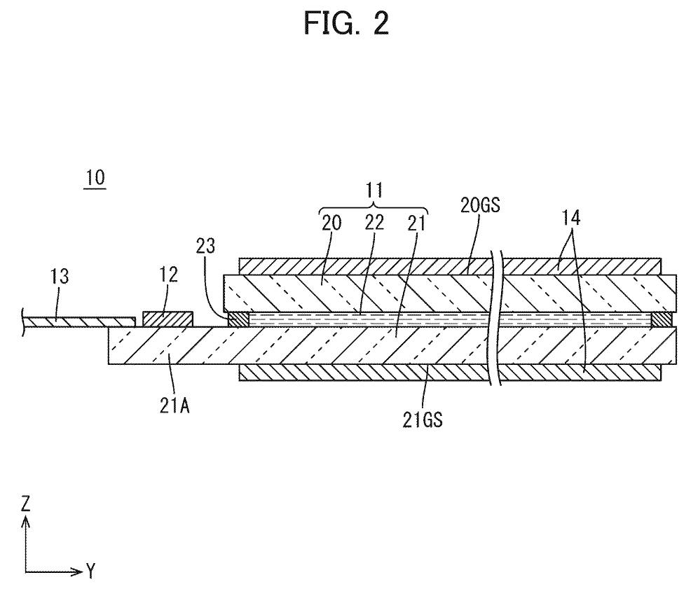

A description is now given of Embodiment 1 with reference to FIGS. 1 to 16. The present embodiment discusses a liquid crystal display device 10 as an example. Note that an X-axis, a Y-axis, and a Z-axis are shown in a part of each drawing, and each axial direction is drawn to be a direction shown in each drawing. In addition, in FIGS. 2, 5 to 9, 11, 13 and 16, the upper side is the front side, and the lower side is the back side.

Referring to FIG. 1, the liquid crystal display device 10 includes at least: a liquid crystal panel (display device, display panel) 11 shaped like a horizontally elongated rectangle where images can be displayed; and a backlight device (lighting device) for illuminating the liquid crystal panel 11 with light for use in producing the displays. The backlight device is disposed on the back side (rear side) of the liquid crystal panel 11 and includes, for example: a white light-emitting light source (e.g., LED); and an optical member for converting light traveling from the light source to areal light by optical operation. The liquid crystal panel 11 has, in a central portion of its primary face, a display area AA where images are displayed. Meanwhile, the liquid crystal panel 11 has, in a frame-shaped peripheral portion of the primary face surrounding the display area AA, a non-display area NAA where no images are displayed.

A description is now given of the liquid crystal panel 11 with reference to FIG. 1 and FIG. 2. Referring to FIGS. 1 and 2, the liquid crystal panel 11 includes a pair of substrates 20 and 21 attached together. Of this pair of substrates 20 and 21, the front side is the opposite substrate 20, and the back side is the array substrate (display substrate) 21. The opposite substrate 20 and the array substrate 21 include: respective glass substrates (transmissive substrates) 20GS and 21GS; and various films stacked on their inner face sides. Between the pair of substrates 20 and 21 is there interposed a liquid crystal layer 22 containing liquid crystal molecules which are a substance that changes its optical properties in response to an electric field applied to it. Between the outer peripheral portions of the pair of substrates 20 and 21 is there interposed a sealing section 23 for sealing the liquid crystal layer 22. The sealing section 23 is shaped like a rectangular frame surrounding the liquid crystal layer 22. Note that a polarizer 14 is attached to each of the outer face sides of the substrates 20 and 21.

Referring to FIGS. 1 and 2, the opposite substrate 20 has a shorter short-side dimension than the array substrate 21. The opposite substrate 20 is attached to the array substrate 21 so that one of the two end portions of each of the substrates in terms of the short-side direction (Y-axis direction) is aligned. Therefore, the other end portion of the array substrate 21 in terms of the short-side direction is an exposed portion 21A that projects sideways from the opposite substrate 20 and hence is exposed. This exposed portion 21A is entirely the non-display area NAA and has, mounted thereto, a flexible substrate 13 and a driver 12 for supplying various signals.

The driver 12 includes an LSI chip containing a drive circuit therein and is COG (chip on glass)-mounted to the exposed portion 21A of the array substrate 21. The driver 12 can process various signals transferred from the flexible substrate 13 and supply various signals (including image signals) to, for example, the source lines 27 in the array substrate 21. The flexible substrate 13 is designated to transfer, for example, the signals transferred from a control board (not shown) to the array substrate 21.

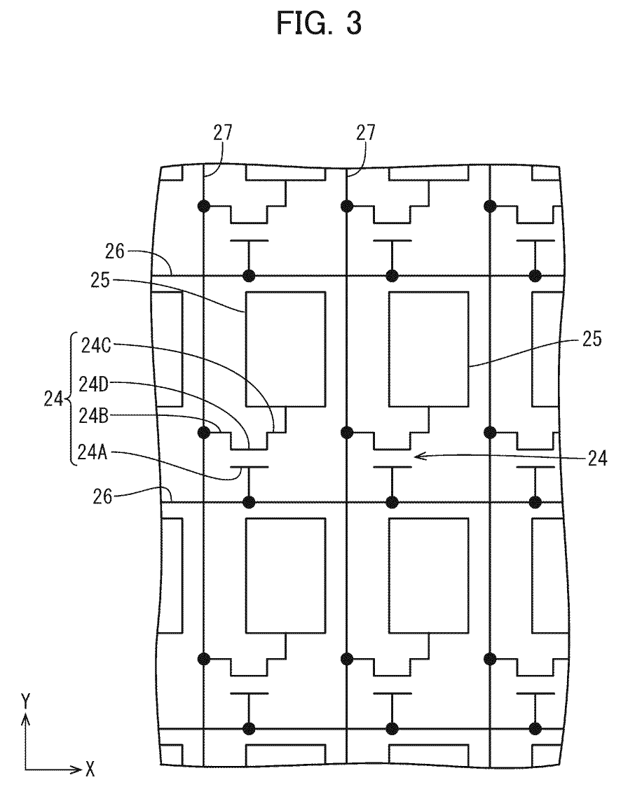

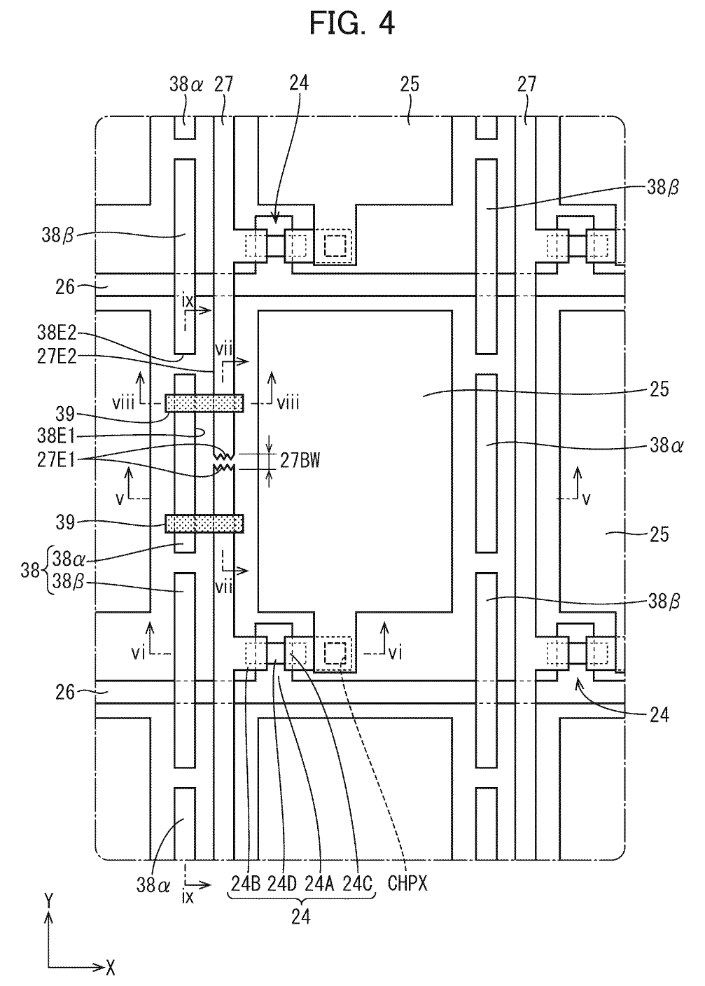

A description is given next of a structure of the display area AA of the array substrate 21 with reference to FIGS. 3 and 4. Referring to FIGS. 3 and 4, the array substrate 21 includes, on the inner face side of the display area AA, at least: TFTs (thin film transistors, switching elements) 24; and pixel electrodes 25. The TFTs 24 and pixel electrodes 25 are arranged in rows and columns at intervals in terms of the X-axis direction and the Y-axis direction like in a matrix. Around the TFTs 24 and the pixel electrodes 25, there are provided gate lines (second wiring lines, scan lines) 26 and source lines (first wiring lines, image lines, signal wiring lines) 27 that intersect orthogonally with (cross) each other. The gate lines 26 extend in the X-axis direction and are disposed at intervals in the Y-axis direction. The source lines 27 extend in the Y-axis direction and are disposed at intervals in the X-axis direction.

Referring to FIGS. 3 and 4, the TFTs 24 are disposed near the intersections of the gate lines 26 and the source lines 27. Each pixel electrode 25 is provided in a region surrounded by one of the gate lines 26 and one of the source lines 27 and has, for example, a vertically elongated, generally rectangular shape in a plan view. Each TFT 24 includes: a gate electrode 24A connected to one of the gate lines 26; a source electrode 24B connected to one of the source lines 27; a drain electrode 24C connected to one of the pixel electrodes 25; and a semiconductor segment 24D connected to the source electrode 24B and the drain electrode 24C. The structure of the TFT 24 will be detailed later.

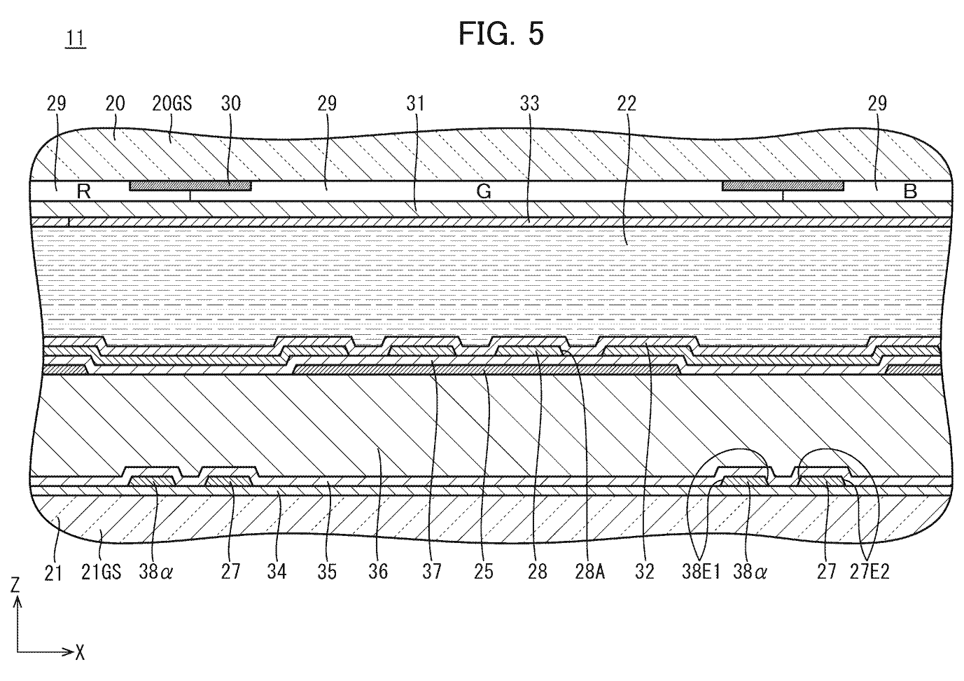

A description is now given of the cross-sectional structure of the pixel electrode 25 near its central portion in terms of the Y-axis direction in the liquid crystal panel 11. On the inner face side of the display area AA of the array substrate 21, a common electrode 28 is provided on the upper layer side of the pixel electrodes 25 so as to overlap all the pixel electrodes 25 as shown in FIG. 5. The common electrode 28 includes a plurality of slits 28A at each location overlapping one of the pixel electrodes 25. The common electrode 28 is fed with a common potential signal (reference potential signal) for a common potential (reference potential) from the control board through the flexible substrate 13 and spreads two-dimensionally across the substantially entire display area AA. As a potential difference develops between the pixel electrode 25 and the common electrode 28, which overlap each other, upon charging the pixel electrode 25, a fringe electric field (oblique electric field) including a component normal to the plate face of the array substrate 21 as well as the components parallel to the primary face of the array substrate 21 develops between the opening edge of the slit 28A in the common electrode 28 and the pixel electrode 25. Therefore, the alignment of the liquid crystal molecules contained in the liquid crystal layer 22 can be controlled by utilizing this fringe electric field. In other words, the liquid crystal panel 11 in accordance with the present embodiment operates in FFS (fringe field switching) mode.

Color filters 29 of three colors that give off blue (B), green (G), and red (R) colors are provided in the display area AA on the inner face side of the opposite substrate 20 in the liquid crystal panel 11 as shown in FIG. 5. The plurality of color filters 29, which give off mutually different colors, are arranged side by side adjacent to each other in the direction in which the gate lines 26 extend (in the X-axis direction). The plurality of color filters 29, which give off mutually different colors, extend in the direction in which the source lines 27 extend (substantially in the Y-axis direction). As described here, the plurality of color filters 29, which give off mutually different colors, are arranged in stripes as a whole. These color filters 29 are disposed overlapping each pixel electrode 25 on the array substrate 21 side in a plan view and, together with the pixel electrodes 25, constitute pixels that are units of display. The plurality of color filters 29, which give off mutually different colors, are disposed so that their boundaries (color boundaries) overlap the source lines 27.

A light-blocking section (black matrix) 30 positioned on the lower layer side of the color filters 29 is provided on the inner face side of the opposite substrate 20 as shown in FIG. 5. The light-blocking section 30 is made of a light-blocking material that has excellent light-blocking properties. The light-blocking section 30 can block light projected by, for example, a backlight device. In the display area AA, the light-blocking section 30 has a substantially lattice-like shape in a plan view to partition those pixel electrodes 25 (pixels) that are adjacent to each other. The light-blocking section 30 is disposed overlapping at least the gate lines 26 and the source lines 27 on the array substrate 21 side in a plan view. In addition, an overcoat film 31 that is disposed all across the substantially entire opposite substrate 20 for the purpose of planarization is provided on the upper layer side (liquid crystal layer 22 side) of the color filters 29. Note that alignment films 32 and 33 for aligning the liquid crystal molecules contained in the liquid crystal layer 22 are provided respectively on the innermost faces (top layers), of the substrates 20 and 21, that are in contact with the liquid crystal layer 22.

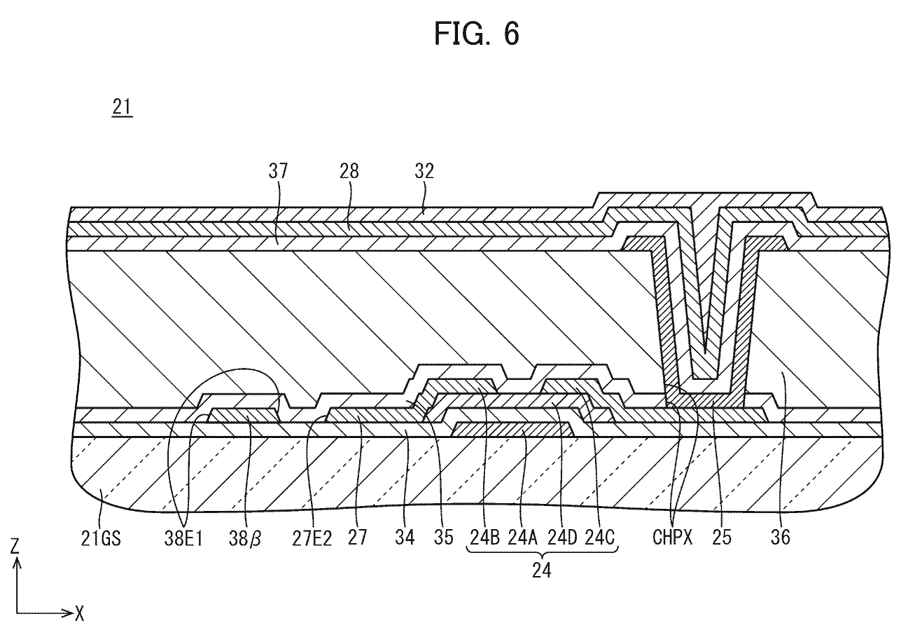

A description is now given of various films stacked on the inner face side of the array substrate 21. Referring to FIG. 6, the array substrate 21 includes a stack of a first metal layer (second conductive layer), a gate insulation film (first insulation film) 34, a semiconductor film, a second metal layer (first conductive layer), a first interlayer insulation film (second insulation film) 35, a planarization film (second insulation film) 36, a first transparent electrode film (third conductive layer), a second interlayer insulation film 37, a second transparent electrode film, and the alignment film 32, all of which are provided in this order when viewed from a lower layer side (from the glass substrate 21GS side). Each of the first metal layer and the second metal layer is either a monolayer film of a single type of metal material selected from, for example, copper, titanium, aluminum, molybdenum, and tungsten or, for example, a film stack or an alloy of different types of metal materials and hence has conductive and light-blocking properties. The first metal layer constitutes, for example, the gate lines 26 and the gate electrodes 24A of the TFTs 24. The second metal layer constitutes, for example, the source lines 27 and the source electrodes 24B and the drain electrodes 24C of the TFTs 24. The semiconductor film is made of, for example, a thin film of, for example, an oxide semiconductor or an amorphous silicon and constitutes, for example, the semiconductor segments 24D of the TFTs 24. The first transparent electrode film and the second transparent electrode film are made of a transparent electrode material (e.g., ITO (indium tin oxide) or IZO (indium zinc oxide)). The first transparent electrode film constitutes, for example, the pixel electrodes 25. The second transparent electrode film constitutes, for example, the common electrode 28. The alignment film 32 is as described above.

Each of the gate insulation film 34, the first interlayer insulation film 35, and the second interlayer insulation film 37 is made of an inorganic material such as silicon nitride (SiNₓ) or silicon oxide (SiO₂). The planarization film 36 is made of an organic material such as PMMA (acrylic resin). The planarization film 36 has a far greater thickness than the gate insulation film 34, the first interlayer insulation film 35, and the second interlayer insulation film 37. This planarization film 36 planarizes the inner face (the face on the liquid crystal layer 22 side) of the array substrate 21. The gate insulation film 34 keeps the first metal layer on the lower layer side insulated from the semiconductor film and the second metal layer on the upper layer side. For example, the intersections of the gate lines 26 made of the first metal layer and the source lines 27 made of the second metal layer are kept insulated from the gate insulation film 34. In addition, in the TFTs 24, the sites where the gate electrodes 24A made of the first metal layer overlap the semiconductor segments 24D made of the semiconductor film are insulated by the gate insulation film 34. The first interlayer insulation film 35 and the planarization film 36 keep the semiconductor film and the second metal layer on the lower layer side insulated from the first transparent electrode film on the upper layer side. The second interlayer insulation film 37 keeps the first transparent electrode film on the lower layer side insulated from the second transparent electrode film on the upper layer side. For example, the sites where the pixel electrodes 25 made of the first transparent electrode film overlap the common electrode 28 made of the second transparent electrode film are kept insulated by the second interlayer insulation film 37.

A description is given next of a cross-sectional structure of the TFT 24. Referring to FIG. 6, each TFT 24 includes the gate electrode 24A made of a part of the first metal layer. The gate electrode 24A is formed by locally broadening a part of the neighborhood of the intersection of the gate line 26 with the source line 27 (see FIG. 4). The TFT 24 includes the source electrode 24B made of a part of the second metal layer. The source electrode 24B is formed by locally broadening a part of the neighborhood of the intersection of the source line 27 with the gate line 26 (see FIG. 4). The source electrode 24B is disposed on one of the X-axis-wise ends (far left end shown in FIG. 6) of the TFT 24, overlaps a part of the gate electrode 24A, and is connected to the semiconductor segment 24D.

Referring to FIG. 6, the TFT 24 includes the drain electrode 24C made of a part of the second metal layer. The drain electrode 24C is disposed at a location that is separated by a distance in the X-axis direction from the source electrode 24B, in other words, at the other X-axis-wise end (far right end shown in FIG. 6) of the TFT 24. The end portion of the drain electrode 24C on the source electrode 24B side is disposed so as to overlap a part of the gate electrode 24A and connected to the semiconductor segment 24D. The end portion of the drain electrode 24C opposite the source electrode 24B side is disposed overlapping a part of the pixel electrode 25. A pixel contact hole CHPX is provided through the first interlayer insulation film 35 and the planarization film 36 at a location, in the first interlayer insulation film 35 and the planarization film 36, overlapping both the drain electrode 24C and the pixel electrode 25. The drain electrode 24C and the pixel electrode 25 are connected to each other through the pixel contact hole CHPX.

Referring to FIG. 6, the TFT 24 has the insular semiconductor segment 24D that includes a channel section. The semiconductor segment 24D has a horizontally elongated shape that extends in the X-axis direction. The semiconductor segment 24D overlaps the gate electrode 24A via the gate insulation film 34. The semiconductor segment 24D is connected at one of its end portions to the source electrode 24B. The semiconductor segment 24D is connected at its other end portion to the drain electrode 24C. A part of the semiconductor segment 24D that overlaps the gate electrode 24A, but that does not overlap the source electrode 24B and the drain electrode 24C is the channel section serving as the channel (current path). The TFT 24 is driven on the basis of a scan signal supplied by the gate line 26 to the gate electrode 24A. This scan signal includes a higher electrical potential than the threshold voltage of the TFT 24. Then, an electrical potential related to an image signal supplied by the source line 27 to the source electrode 24B is supplied to the drain electrode 24C through the channel region created in the semiconductor segment 24D. As a result, the pixel electrode 25 is charged to the electrical potential related to the image signal.

Incidentally, the source line 27, which extends in the Y-axis direction in the display area AA of the array substrate 21, can in some cases develop a broken portion 27BW as a defect as shown in FIG. 4. When this is actually the case, there is a concern that the image signal is supplied to those TFTs 24 that are connected to the part of the source line 27 that resides on the driver 12 side of the broken portion 27BW (lower side in FIG. 4), whereas the image signal is not supplied to those TFTs 24 that are connected to the part of the source line 27 that resides on the side of the broken portion 27BW opposite the driver 12 (upper side in FIG. 4). The signal line is repaired by irradiating, with laser, the correction-use overlapping segment of a light-blocking film overlapping the broken signal line to restore electrical conductance between the signal line and the light-blocking film in the related art. However, there are cases where the light-blocking film and the signal line may not be properly connected by laser irradiation, depending on conditions including the shape of the site in the broken signal line irradiated with a laser beam.

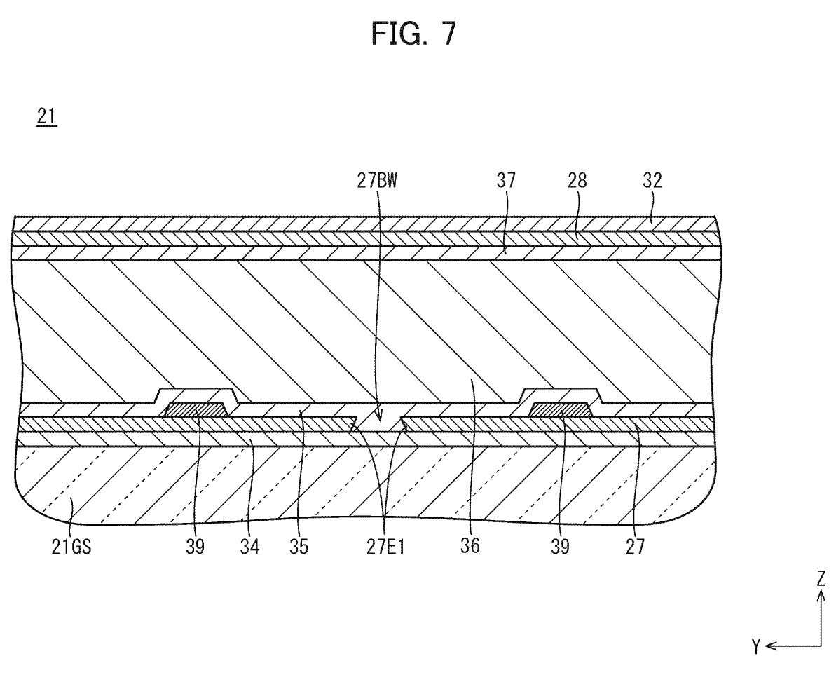

Meanwhile, the source line 27 that has developed the broken portion 27BW can be repaired by directly providing (applying) a conductive member to the broken portion 27BW of the source line 27, without using the known light-blocking film. However, at a first end portion 27E1 of the source line 27 that is an end portion facing the broken portion 27BW, the source line 27 can have a reverse-tapered (overhanging) cross-sectional shape in terms of the Y-axis direction as shown in FIG. 7. “Reverse-tapered” refers to a shape of the first end portion 27E1 of the source line 27 in which the upper end segment of the first end portion 27E1 of the source line 27 juts out over the lower end segment that is in contact with the base layer (gate insulation film 34) like an eave in such a manner that there is an empty gap between the first end portion 27E1 and the base layer. If a conductive member is directly provided to the broken portion 27BW of the source line 27 in such a case, the conductive member may possibly only insufficiently cover the reverse-tapered, first end portion 27E1, and the conductive member could fail to restore conductance between the two first end portions 27E1 facing the broken portion 27BW. Therefore, the reliability of normalizing the source line 27 through repair is not necessarily satisfactory.

Accordingly, in the display area AA of the array substrate 21 in accordance with the present embodiment, there is provided a repairing wiring line 38 at a location that is separated by a distance in the X-axis direction from the source line 27 as shown in FIG. 4. Specifically, the repairing wiring line 38 is disposed so as to sandwich the source line 27 between the repairing wiring line 38 and the pixel electrode 25 in terms of the X-axis direction. The source line 27 that is sandwiched between the repairing wiring line 38 and the pixel electrode 25 is connected through the TFT 24 to the pixel electrode 25 that is adjacent to the source line 27 on the opposite side from the repairing wiring line 38 in terms of the X-axis direction. Each repairing wiring line 38 extends in the Y-axis direction parallel to the source line 27, and a plurality of repairing wiring lines 38 are arranged end to end at intervals in the Y-axis direction. The plurality of repairing wiring lines 38 are arranged end to end along a straight line in the Y-axis direction, thereby forming a single column of repairing wiring lines 38. The lengthwise dimension (dimension in the Y-axis direction) of each of the plurality of repairing wiring lines 38 is shorter than the lengthwise dimension of the source line 27 and is approximately equal to, or shorter than, the lengthwise dimension of the pixel electrode 25 (pixel).

Referring to FIGS. 5 and 6, the repairing wiring line 38 is made of a part of the same second metal layer as is the source line 27. In other words, the repairing wiring line 38 is positioned in the same layer in the array substrate 21 as the source line 27. Referring to FIG. 4, the plurality of repairing wiring lines 38 include: those repairing wiring lines 38 that do not cross the gate lines 26 (hereinafter, the “first repairing wiring lines 38α”); and those repairing wiring lines 38 that cross the gate lines 26 (hereinafter, the “second repairing wiring lines 38β”). The first repairing wiring lines 38α and the second repairing wiring lines 38β are arranged end to end alternatively and repeatedly in terms of the Y-axis direction. Referring to FIGS. 4 and 5, each first repairing wiring line 38α is positioned between two of the gate lines 26 sandwiching the pixel electrode 25 in terms of the Y-axis direction and is interposed, along its entire length, between the pixel electrode 25 and the source line 27 in terms of the X-axis direction. Referring to FIGS. 4 and 6, the second repairing wiring line 38β extends in the Y-axis direction both upwards and downwards in FIG. 4 from the gate line 26 and includes, for example, a portion interposed between the TFT 24 and the source line 27 in terms of the X-axis direction and a portion interposed between the pixel electrode 25 and the source line 27 in terms of the X-axis direction. Each second repairing wiring line 38β crosses the gate line 26 made of a part of the first metal layer via the gate insulation film 34. The second repairing wiring line 38β and the gate line 26 that cross each other are kept insulated by the gate insulation film 34.

On top of that, the present embodiment is configured to repair the defect of the source line 27 by providing first connecting segments 39 for connecting the source line 27 and the repairing wiring line 38 as shown in FIG. 4. Each first connecting segment 39 is made of a part of a conductive member disposed on the lower layer side of the first interlayer insulation film 35 on the upper layer side of the second metal layer. The conductive member contains a highly conductive metal material. To provide the first connecting segments 39, a conductive member such as tungsten needs only to be selectively provided in prescribed regions on the array substrate 21 by using, for example, a laser CVD (chemical vapor deposition) device. Alternatively, to provide the first connecting segments 39, for example, a conductive adhesive (conductive member) such as a silver paste needs only to be selectively applied to prescribed regions on the array substrate 21. The conductive adhesive is prepared by dispersing and hence blending many conductive particles (e.g., silver particles) in a binder made of a resin material.

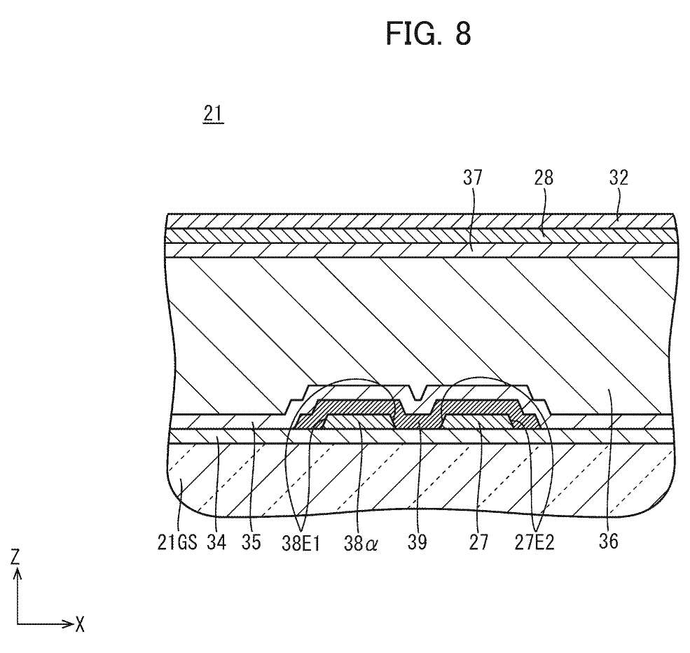

Referring to FIGS. 4 and 8, the first connecting segment 39 extends in the X-axis direction across the source line 27 to be repaired and the repairing wiring line 38 that is adjacent at a distance to this source line 27 and is connected to each of the source line 27 and the repairing wiring line 38. Two first connecting segments 39 are provided for connection at two locations, in the source line 27, that sandwich the defect in terms of the Y-axis direction. Which of the two first connecting segments 39 is connected to which of the plurality of repairing wiring lines 38 is specified in accordance with, for example, the location of the defect of the source line 27 in terms of the Y-axis direction and the range (dimensions) of the defect in terms of the Y-axis direction. As an example, when the location of the broken portion 27BW in the source line 27 in terms of the Y-axis direction overlaps the central portion (portion excluding the two end portions) of a single one of the plurality of repairing wiring lines 38 in the Y-axis direction, and the range of the broken portion 27BW in terms of the Y-axis direction is sufficiently smaller than the lengthwise dimension of the repairing wiring line 38, the two first connecting segments 39 are connected to that single one of the plurality of repairing wiring lines 38. The first connecting segment 39 is preferably provided so as not to come into contact with one of the first end portions 27E1, of the source line 27, that faces the broken portion 27BW.

As described here, even when the source line 27 has a defect, the connection of the source line 27 and the repairing wiring line 38 by the first connecting segments 39 enables the signal transmission on the source line 27 to be maintained via the repairing wiring line 38 and the first connecting segments 39. In the present embodiment, each of the source line 27 and the repairing wiring line 38 is made of a part of the second metal layer, and the first connecting segment 39 is made of a part of a conductive member disposed on the upper layer side of the second metal layer. In other words, the first connecting segment 39 can be directly connected to the source line 27 and the repairing wiring line 38 from the upper layer side. This particular structure improves connection reliability and increases the reliability of normalizing the source line 27 through repair, in comparison with when the signal line and the correction-use overlapping segment of the light-blocking film that overlap via a gate insulation film are connected by laser irradiation as in a known manner. In addition, the first connecting segment 39 is not provided extending in the Y-axis direction with respect to the first end portion 27E1 even when the first end portion 27E1 of the source line 27, facing the broken portion 27BW, has a reverse-tapered cross-sectional shape in terms of the Y-axis direction (see FIG. 7). The first connecting segment 39 is provided extending in a direction that crosses the source line 27 and the repairing wiring line 38 (including the X-axis direction) and for this reason, achieves satisfactory coverage for the source line 27 and the repairing wiring line 38. Hence, the structure gives satisfactory connection reliability for the source line 27 and the repairing wiring line 38 and increases the reliability of normalizing the source line 27 through repair.

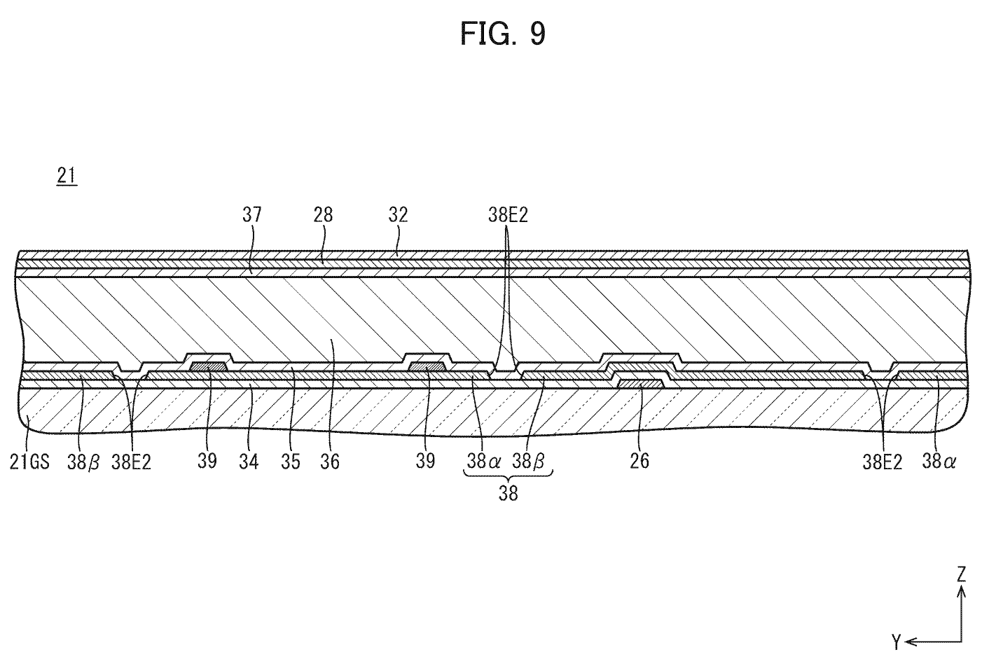

Besides, the source line 27 has a second end portion 27E2 that is an end portion in terms of the X-axis direction with a forward-tapered cross-sectional shape as shown in FIG. 8. Each of the plurality of repairing wiring lines 38 has a third end portion 38E1 that is an end portion in terms of the X-axis direction with a forward-tapered cross-sectional shape. “Forward-tapered” refers to a shape of each of the end portions 27E2 and 38E1 in which the lower end segment, of the end portions 27E2 and 38E1, that is in contact with the base layer (gate insulation film 34) juts out below the upper end segment. This structure enables the first connecting segment 39 to satisfactorily cover the source line 27 and the repairing wiring line 38. Hence, the structure improves the connection reliability of the first connecting segment 39 for the source line 27 and the repairing wiring line 38 and for this reason, further increases the reliability of normalizing the source line 27 through repair. In addition, referring to FIG. 9, each of the plurality of repairing wiring lines 38 has fourth end portions 38E2 that are end portions in terms of the Y-axis direction with a forward-tapered cross-sectional shape.

The present embodiment is configured as described so far, and a description is given next of a method of manufacturing the liquid crystal panel 11. A method of manufacturing the liquid crystal panel 11 includes: an opposite substrate manufacturing step of manufacturing the opposite substrate 20; an array substrate manufacturing step of manufacturing the array substrate 21; and an attaching step of attaching the manufactured opposite substrate 20 and the manufactured array substrate 21. Of these steps, the following description will focus on the array substrate manufacturing step (method of manufacturing the array substrate 21).

The array substrate manufacturing step includes at least: a first step of forming and patterning the first metal layer; a second step of forming the gate insulation film 34; a third step of forming and patterning the semiconductor film; a fourth step of forming and patterning the second metal layer; a fifth step of forming the first interlayer insulation film 35; a sixth step of forming and patterning the planarization film 36; a seventh step of forming and patterning the first transparent electrode film; an eighth step of forming the second interlayer insulation film 37; a ninth step of forming and patterning the second transparent electrode film; and a tenth step of forming the alignment film 32. The array substrate manufacturing step in accordance with the present embodiment includes, between the fifth step and the sixth step: an inspection step of inspecting the source lines 27 made of the second metal layer; and a repair step of repairing the source line 27. The following description will focus on the fourth step, the inspection step, and the repair step.

Note that the term “patterning” above refers to the fabrication of a film based on ordinary photolithography. Specifically, a workpiece film is fabricated, in other words, patterned by forming a photoresist film on the workpiece film, exposing the photoresist film to light by an exposure device via a photomask that has a prescribed pattern of openings, thereafter developing the photoresist film, and etching via the developed photoresist film.

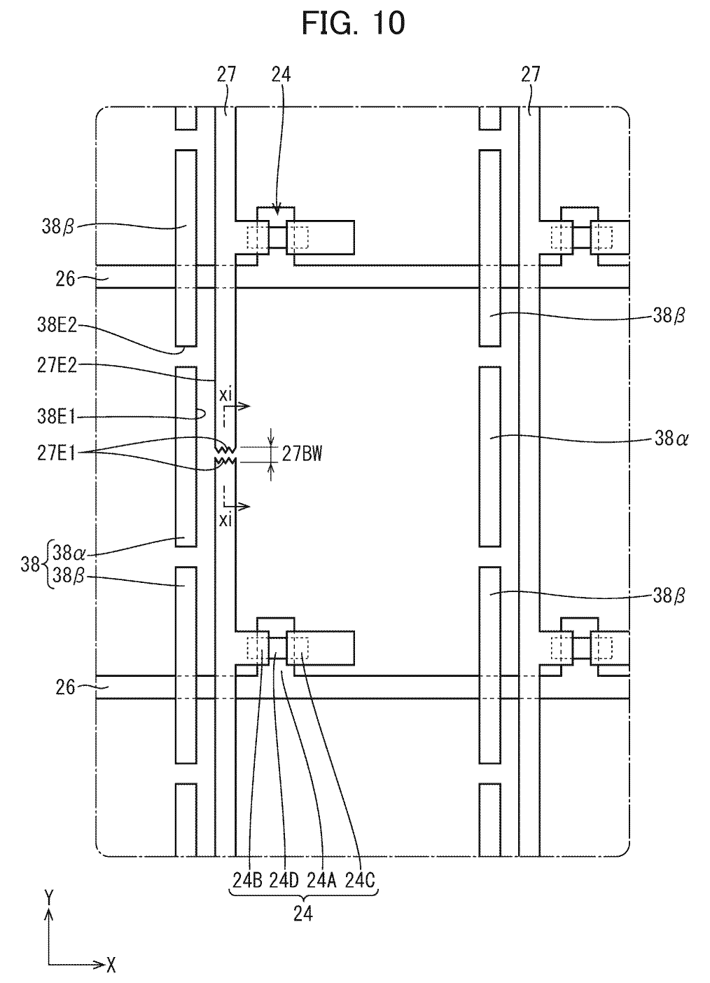

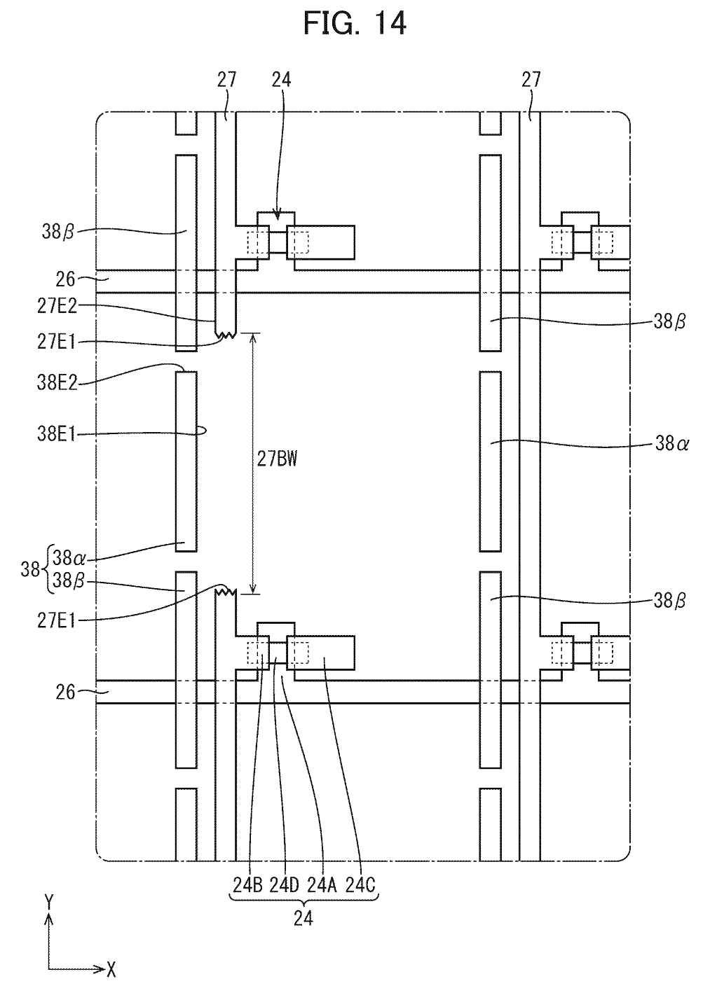

In the fourth step, the second metal layer is formed on the semiconductor film and selectively etched away by photolithography. Hence, the source electrodes 24B, the drain electrodes 24C, and the source lines 27 of the TFTs 24 are formed (see FIGS. 10 and 14). Thereafter, in the inspection step, if there is a source line 27 that has a defect, the source line 27 can be detected by inputting an inspection signal to the plurality of source lines 27 that are made of a part of the second metal layer by using an inspection device. Furthermore, the inspection step identifies, in the source line 27 that has a defect, for example, the location of the defect in terms of the Y-axis direction and the range of the defect in terms of the Y-axis direction. To determine the location, range, and the like of the defect, for example, the source line 27 that has a defect may be visually checked by an inspector under, for example, an electron microscope, or an image of the source line 27 that has a defect may be captured using an imaging-capturing device and subjected to image processing.

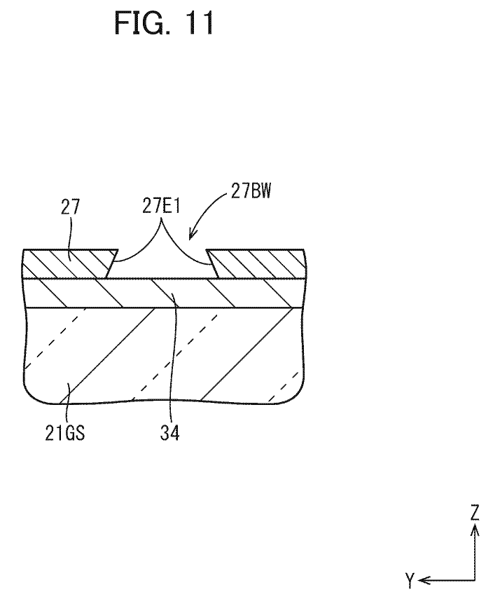

The description now discusses a case where the results of inspection of the inspection step show that the broken portion 27BW has occurred at the location and with the range shown in FIGS. 10 and 11 as a defect of the source line 27. In such a case, the location of the broken portion 27BW in the source line 27 in terms of the Y-axis direction overlaps the central portion (portion excluding the two end portions) of the first repairing wiring line 38α in the plurality of repairing wiring lines 38 in terms of the Y-axis direction, and the range of the broken portion 27BW in the Y-axis direction is sufficiently smaller than the lengthwise dimension of the first repairing wiring line 38α.

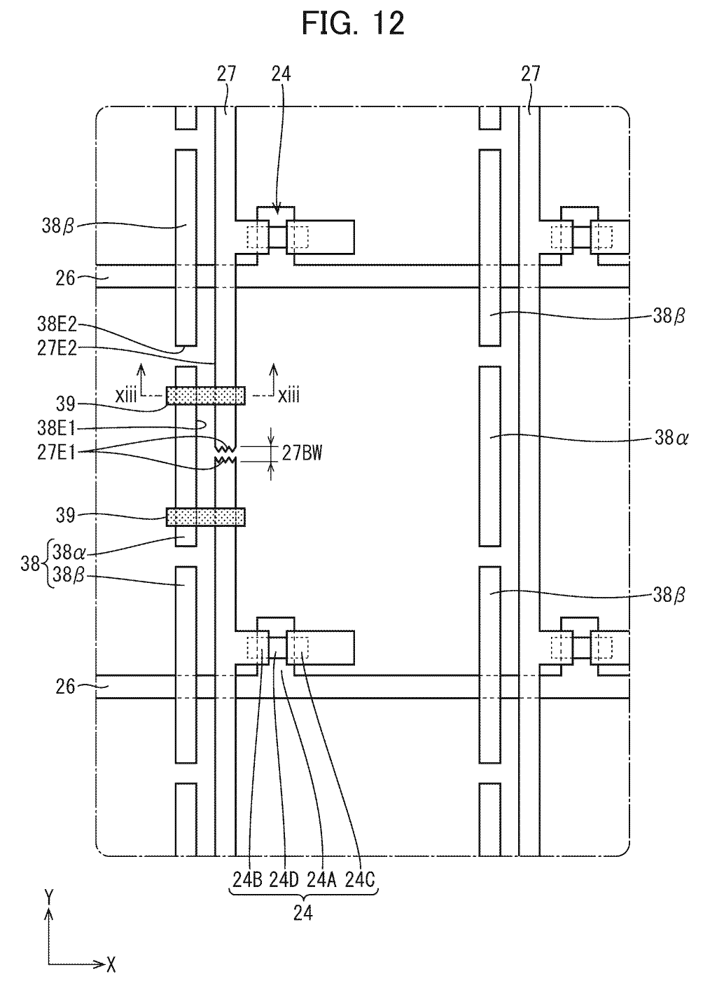

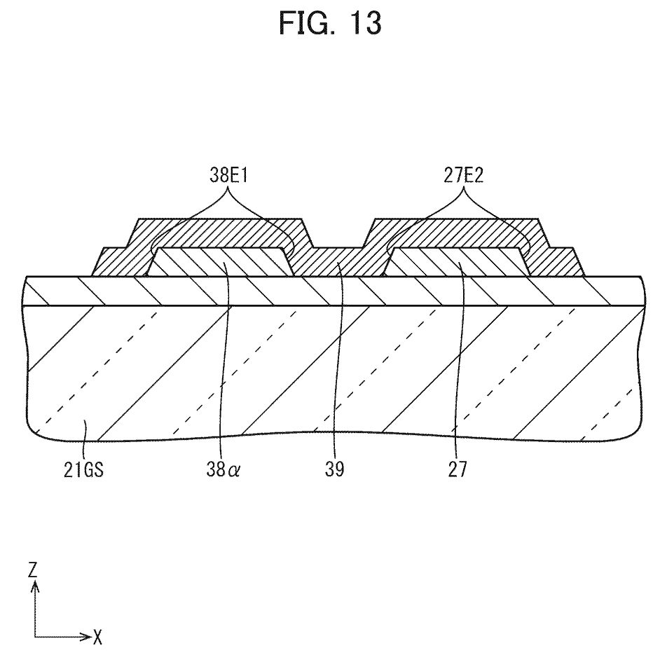

In the repair step, the two first connecting segments 39 are connected, as shown in FIGS. 12 and 13, to the source line 27 that includes the broken portion 27BW and to a single first repairing wiring line 38α that is adjacent to the broken portion 27BW in the X-axis direction, shown in FIGS. 10 and 11. The two first connecting segments 39 are disposed at two locations that sandwich the broken portion 27BW in terms of the Y-axis direction. The two first connecting segments 39 may be selectively provided in prescribed regions by using a laser CVD device and may alternatively be selectively provided in prescribed regions by applying a conductive adhesive. This structure allows the image signal supplied from the driver 12 to the source line 27 that includes the broken portion 27BW to be transferred from a part of the source line 27 that is on the driver 12 side to a part of the source line 27 that is opposite the driver 12 via the two first connecting segments 39 and the single first repairing wiring line 38α. Since the connection reliability of the first connecting segment 39 for the source line 27 and the first repairing wiring line 38α is sufficiently increased, the reliability of normalizing the source line 27 through repair is increased.

The description now discusses a case where the results of inspection of the inspection step show that the broken portion 27BW has occurred at the location and with the range shown in FIG. 14 as a defect of the source line 27. In such a case, the location and range of the broken portion 27BW in the source line 27 in the Y-axis direction overlap the entirety of a first repairing wiring line 38α in the plurality of repairing wiring lines 38 and additionally overlap parts of the two second repairing wiring lines 38β that are upwardly and downwardly adjacent in FIG. 14 to that first repairing wiring line 38α in terms of the Y-axis direction. In other words, the broken portion 27BW shown in FIG. 14 has occurred in a range across three (two or more) of the repairing wiring lines 38 in terms of the Y-axis direction.

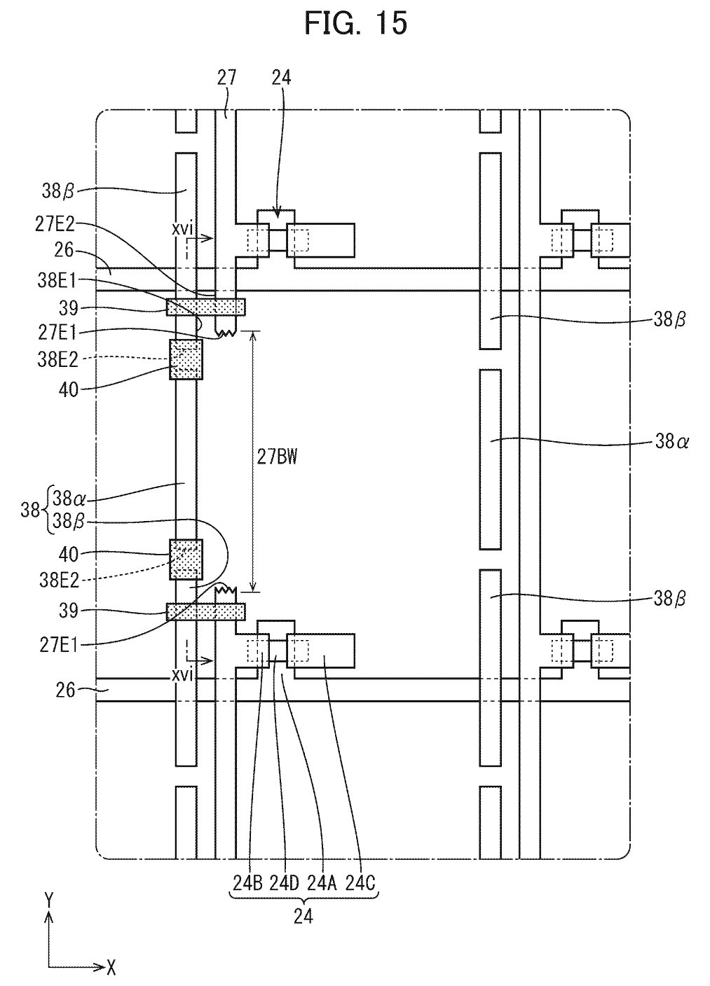

In the repair step, the two first connecting segments 39 are connected, as shown in FIG. 15, to the source line 27 that includes the broken portion 27BW and to the two second repairing wiring lines 38β that are adjacent to the broken portion 27BW in the X-axis direction, shown in FIG. 14. The two first connecting segments 39 are disposed at two locations that sandwich the broken portion 27BW in terms of the Y-axis direction. In addition, two second connecting segments 40 are connected to a single first repairing wiring line 38α that is adjacent to the broken portion 27BW in the X-axis direction and to two second repairing wiring lines 38β that are adjacent to the broken portion 27BW in the X-axis direction.

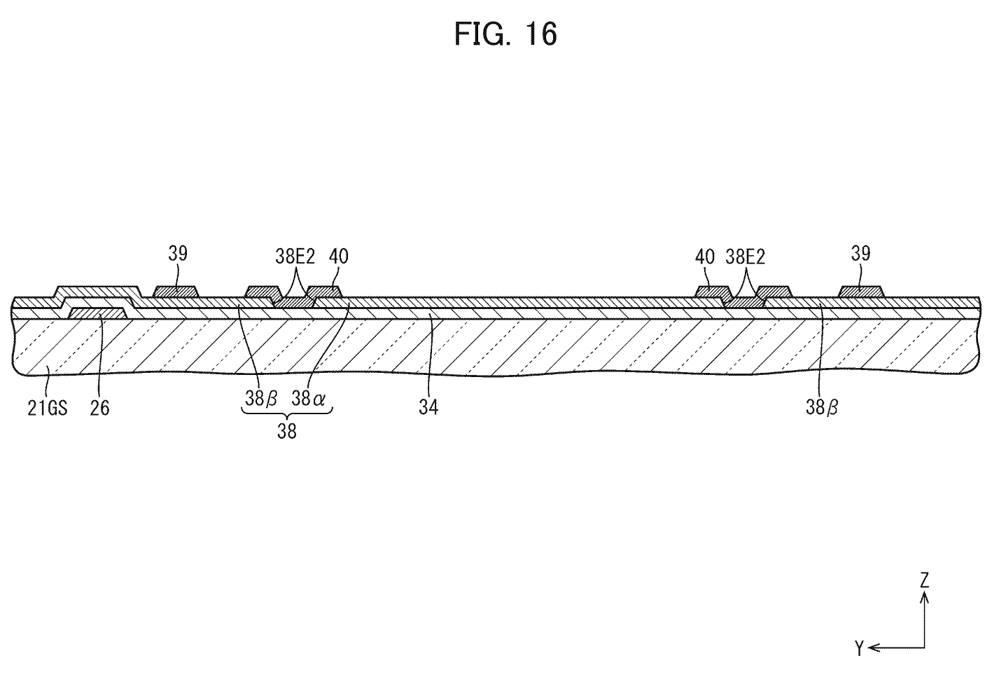

Here, the second connecting segment 40 is made of a part of a conductive member that is common to the first connecting segment 39 and is directly connected to the two repairing wiring lines 38 made of a part of the second metal layer from the upper layer side as shown in FIG. 16, and for these reasons, connection reliability is improved over known cases. One of the two second connecting segments 40 extends across the first repairing wiring line 38α and the second repairing wiring line 38β that is adjacent to one of the ends (upper end in FIG. 14) of the first repairing wiring line 38α in the Y-axis direction and is connected to each of these first and second repairing wiring lines 38α and 38β. The other one of the two second connecting segments 40 extends across the first repairing wiring line 38α and the second repairing wiring line 38β that is adjacent to the other end (lower end in FIG. 14) of the first repairing wiring line 38α in the Y-axis direction and is connected to each of these first and second repairing wiring lines 38α and 38β. The two second connecting segments 40 may be selectively provided in prescribed regions by using a laser CVD device and may alternatively be selectively provided in prescribed regions by applying a conductive adhesive. The three repairing wiring lines 38 that are adjacent to each other in the Y-axis direction are connected via the two second connecting segments 40 as described here. Then, of the three repairing wiring lines 38, the two second repairing wiring lines 38β that are positioned at both ends in terms of the Y-axis direction are connected to the source line 27 that includes the broken portion 27BW via the two first connecting segments 39.

This structure allows the image signal supplied from the driver 12 to the source line 27 that includes the broken portion 27BW to be transferred from a part of the source line 27 that is on the driver 12 side to a part of the source line 27 that is opposite the driver 12 via the two first connecting segments 39, the two second connecting segments 40, the single first repairing wiring line 38α, and the two second repairing wiring lines 38β. Since the connection reliability of the first connecting segment 39 for the source line 27 and the second repairing wiring lines 38β is sufficiently increased, and the connection reliability of the second connecting segment 40 for the first repairing wiring line 38α and the second repairing wiring lines 38β is also sufficiently increased, the reliability of normalizing the source line 27 through repair is increased.

Besides, each of the plurality of repairing wiring lines 38 has the fourth end portions 38E2 that are end portions in terms of the Y-axis direction with a forward-tapered cross-sectional shape as shown in FIG. 16, and for this reason, the second connecting segment 40 satisfactorily covers the two repairing wiring lines 38 that are adjacent to each other in the Y-axis direction. Hence, this structure improves the connection reliability of the second connecting segment 40 for the two repairing wiring lines 38 that are adjacent to each other in the Y-axis direction and for this reason, further increases the reliability of normalizing the source line 27 through repair.

As described above, the array substrate (wiring board) 21 in accordance with the present embodiment includes: a source line (first wiring line) 27 including a part of a second metal layer (first conductive layer) and extending in a first direction; a repairing wiring line 38 including a part of the second metal layer, disposed at a location that is separated by a distance from the source line 27, and extending in the first direction; and a first connecting segment 39 including a part of a conductive member, extending across the source line 27 and the repairing wiring line 38, and connected to each of the source line 27 and the repairing wiring line 38, the conductive member being provided on an upper layer side of the second metal layer, wherein the repairing wiring line 38 is shorter in the first direction than the source line 27 and includes a plurality of repairing wiring lines 38 arranged at intervals in the first direction.

The plurality of repairing wiring lines 38 arranged at intervals in the first direction include the repairing wiring line 38 connected to the source line 27 by the first connecting segment 39. Hence, even when the source line 27 has a defect, the signal transmission on the source line 27 can be maintained via the repairing wiring line 38 and the first connecting segment 39. Each of the source line 27 and the repairing wiring line 38 is made of a part of the second metal layer, and the first connecting segment 39 is made of a part of a conductive member disposed on the upper layer side of the second metal layer. In other words, the first connecting segment 39 can be directly connected to the source line 27 and the repairing wiring line 38 from the upper layer side. This particular structure improves connection reliability and increases the reliability of normalizing the source line 27 through repair, in comparison with when the signal line and the correction-use overlapping segment of the light-blocking film that overlap each other via a gate insulation film are connected by laser irradiation as in a known manner.

In addition, each of the source line 27 and the plurality of repairing wiring lines 38 has a second end portion 27E2 and a third end portion 38E1 that are end portions in terms of a second direction that crosses the first direction, the end portions having a forward-tapered cross-sectional shape. The first connecting segment 39 achieves satisfactory coverage for the source line 27 and the repairing wiring line 38. Hence, the connection reliability of the first connecting segment 39 is improved for the source line 27 and the repairing wiring line 38, and for this reason, the reliability of normalizing the source line 27 through repair is further increased.

In addition, the array substrate 21 further includes a second connecting segment 40 including a part of the conductive member, extending across two of the plurality of repairing wiring lines 38 that are adjacent to each other in the first direction, and connected to each of the two of the plurality of repairing wiring lines 38. Even when the source line 27 has a defect in a range across two or more of the plurality of repairing wiring lines 38 in terms of the first direction, the two repairing wiring lines 38 that are adjacent to each other in the first direction can be connected by the second connecting segment 40. Even when the source line 27 has a defect in a range across two or more of the plurality of repairing wiring lines 38 in terms of the first direction, the signal transmission on the source line 27 can be maintained via the two repairing wiring lines 38 that are adjacent to each other in the first direction and the second connecting segment 40. The second connecting segment 40 made of a part of the conductive member is directly connected to the two repairing wiring lines 38 from the upper layer side, and for this reason, connection reliability is improved over known cases, which in turn increases the reliability of normalizing the source line 27 through repair.

In addition, each of the plurality of repairing wiring lines 38 has a fourth end portion 38E2 that is an end portion in terms of the first direction, the end portions having a forward-tapered cross-sectional shape. The second connecting segment 40 achieves satisfactory coverage for the two repairing wiring lines 38 that are adjacent to each other in the first direction. Hence, the connection reliability of the second connecting segment 40 is improved for the two repairing wiring lines 38 that are adjacent to each other in the first direction, and for this reason, the reliability of normalizing the source line 27 through repair is further increased.

In addition, the first connecting segment 39 includes two first connecting segments 39 that are separated by a distance in the first direction, and the source line 27 has a broken portion 27BW at a location sandwiched between the two first connecting segments 39 that are separated by a distance in the first direction. Even when the source line 27 has the broken portion 27BW as a defect, the signal transmission on the source line 27 can be maintained via the repairing wiring line 38 and the first connecting segment 39.

In addition, the liquid crystal panel (display device) 11 in accordance with the present embodiment includes: the array substrate 21 described above; and an opposite substrate 20 disposed opposite the array substrate 21. This liquid crystal panel 11 increases the reliability of normalizing the source line 27 through repair and for this reason, the yield for the liquid crystal panel 11 can be improved.

In addition, a method of manufacturing the array substrate 21 in accordance with the present embodiment includes: providing a source line 27 including a part of a second metal layer and extending in a first direction; providing a plurality of repairing wiring lines 38 arranged at intervals in the first direction, each of the plurality of repairing wiring lines 38 including a part of the second metal layer, disposed at a location that is separated by a distance from the source line 27, extending in the first direction, and being shorter in the first direction than the source line 27; and providing a first connecting segment 39 including a part of a conductive member, extending across the source line 27 and the plurality of repairing wiring lines 38, and connected to each of the source line 27 and the plurality of repairing wiring lines 38, the conductive member being provided on an upper layer side of the second metal layer.

When the source line 27 has a defect, one of the plurality of repairing wiring lines 38 disposed at a location separated by a distance from the source line 27 and the source line 27 are connected by the first connecting segment 39. This particular structure enables the signal transmission on the source line 27 to be maintained via the repairing wiring line 38 and the first connecting segment 39. Each of the source line 27 and the repairing wiring line 38 is made of a part the second metal layer, and the first connecting segment 39 is made of a part of a conductive member disposed on the upper layer side of the second metal layer. In other words, the first connecting segment 39 can be directly connected to the source line 27 and the repairing wiring line 38 from the upper layer side. This particular structure improves connection reliability and increases the reliability of normalizing the source line 27 through repair, in comparison with when the signal line and the correction-use overlapping segment of the light-blocking film that overlap each other via a gate insulation film are connected by laser irradiation as in a known manner.

### Other Embodiments

The techniques disclosed in the present specification are not necessarily limited to the embodiments discussed in the foregoing description with reference to drawings, and as an example, the following embodiments are also encompassed in the technical scope of the present disclosure.
1. The defects of the source line 27 may include, for example, a portion where the line width is locally reduced (portion that is about to break), as well as the broken portion 27BW. The source line 27 with this type of defect is capable of signal transmission at first, but as time goes by, may eventually break and become incapable of signal transmission. The provision of, for example, the first connecting segment 39 and the second connecting segment 40 can repair the source line 27 with such a defect.
2. The source line 27 is not necessarily repaired as shown in FIG. 12 and may be repaired by connecting two first connecting segments 39 to a single second repairing wiring line 38β, depending on the location of the broken portion 27BW.
3. The source line 27 is not necessarily repaired as shown in FIG. 15 and may be repaired by connecting a single second connecting segment 40 to two repairing wiring lines 38 that are adjacent to each other in the Y-axis direction and also connecting a single first connecting segment 39 to each of the two repairing wiring lines 38 connected together by the second connecting segment 40, depending on the range of the broken portion 27BW. Alternatively, the source line 27 may be repaired by connecting three or more second connecting segments 40 to four or more repairing wiring lines 38 that are adjacent to each other in the Y-axis direction and also connecting a single first connecting segment 39 to each of the two repairing wiring lines 38 that are, among the four or more repairing wiring lines 38 that are connected together by three or more second connecting segments 40, positioned on both ends of the four or more repairing wiring lines 38 in terms of the Y-axis direction.
4. The first connecting segment 39 may extend in a direction tilted against both the X-axis direction and the Y-axis direction. In short, the first connecting segment 39 needs only to extend in a direction that crosses the source line 27.
5. There may be provided three or more first connecting segments 39.
6. The length of the repairing wiring line 38 in the Y-axis direction is not necessarily as shown in drawings and may be altered where appropriate. As an example, the length of the repairing wiring line 38 in the Y-axis direction may be shorter than shown in drawings so that a plurality of first repairing wiring lines 38α that do not cross the gate line 26 can be arranged side by side in a continuous sequence. In addition, the length of the repairing wiring line 38 in the Y-axis direction may be greater than the length of the pixel electrode 25 in the Y-axis direction.
7. If a laser CVD device is used to provide, for example, the first connecting segment 39 and the second connecting segment 40, the conductive member may be made of a material other than tungsten.
8. If a conductive adhesive is used as the conductive member, the conductive member may be made of a material other than silver pastes.
9. A device other than a laser CVD device may be used to form the conductive member in a limited range to provide, for example, the first connecting segment 39 and the second connecting segment 40.
10. The source line 27 does not necessarily have a planar structure in which the source line 27 extends straightly in the Y-axis direction and may have a planar structure in which the source line 27 is bent repeatedly. When this is the case, the plurality of repairing wiring lines 38 may have a planar structure in which the plurality of repairing wiring lines 38 are disposed parallel to the source line 27 and as a whole, bent repeatedly.
11. The TFT 24 does not necessarily have a bottom gate structure and may have, for example, a top gate structure or a double gate structure.
12. The semiconductor film may be made of a polycrystalline polysilicon material.
13. In the non-display area NAA the array substrate 21, for example, a gate drive circuit (GDM (gate driver monolithic) circuit) for supplying a scan signal to the gate lines 26 and a switch circuit (SSD (source shared driving) circuit) for distributing an image signal supplied from the driver 12 to the plurality of source lines 27 may be provided monolithically by using various films on the glass substrate 21GS.
14. The array substrate 21 does not necessarily include the glass substrate 21GS as the transmissive substrate and may include a resin substrate made of a synthetic resin as the transmissive substrate.
15. The driver 12 may be COF (chip on film)-mounted to the flexible substrate 13 that is in turn FOG (film on glass)-mounted to the array substrate 21.
16. The liquid crystal panel 11 may have a plan-view shape such as a vertically elongated rectangle, a square, a circle, a semicircle, a vertically elongated circle, an ellipse, or a trapezoid.
17. The liquid crystal panel 11 does not necessarily produce displays in FFS mode and may do so in any mode including TN (twisted nematic) mode, VA (vertical alignment) mode, and IPS (in-plane switching) mode.
18. The display device is not necessarily the liquid crystal panel 11 and may be, for example, an organic EL (electro luminescence) display panel or an EPD (microencapsulated electrophoretic) display panel.

What is claimed is:

1. A wiring board comprising:
a first wiring line including a part of a first conductive layer and extending in a first direction;
a repairing wiring line including a part of the first conductive layer, disposed at a location that is separated by a distance from the first wiring line, and extending in the first direction; and
a first connecting segment including a part of a conductive member, extending across the first wiring line and the repairing wiring line, and connected to each of the first wiring line and the repairing wiring line, the conductive member being provided on an upper layer side of the first conductive layer, wherein
the repairing wiring line is shorter in the first direction than the first wiring line and comprises a plurality of repairing wiring lines arranged at intervals in the first direction.

2. The wiring board according to claim 1, wherein each of the first wiring line and the plurality of repairing wiring lines has an end portion in terms of a second direction that crosses the first direction, the end portions having a forward-tapered cross-sectional shape.

3. The wiring board according to claim 1, further comprising a second connecting segment including a part of the conductive member, extending across two of the plurality of repairing wiring lines that are adjacent to each other in the first direction, and connected to each of the two of the plurality of repairing wiring lines.

4. The wiring board according to claim 3, wherein each of the plurality of repairing wiring lines has an end portion in terms of the first direction, the end portions having a forward-tapered cross-sectional shape.

5. The wiring board according to claim 1, wherein
the first connecting segment comprises two first connecting segments that are separated by a distance in the first direction, and
the first wiring line has a broken portion at a location sandwiched between the two first connecting segments that are separated by a distance in the first direction.

6. A display device comprising:
the wiring board according to claim 1; and
an opposite substrate disposed opposite the wiring board.

7. A method of manufacturing a wiring board, the method comprising:
providing a first wiring line including a part of a first conductive layer and extending in a first direction;
providing a plurality of repairing wiring lines arranged at intervals in the first direction, each of the plurality of repairing wiring lines including a part of the first conductive layer, disposed at a location that is separated by a distance from the first wiring line, extending in the first direction, and being shorter in the first direction than the first wiring line; and
providing a first connecting segment including a part of a conductive member, extending across the first wiring line and the plurality of repairing wiring lines, and connected to each of the first wiring line and the plurality of repairing wiring lines, the conductive member being provided on an upper layer side of the first conductive layer.
